(19) United States
(12) Patent Application Publication
(10) Pub. No.: US 2025/0349705 A1
(43) Pub. Date: Nov. 13, 2025

(54) BEOL TRENCH AND VIA STRUCTURE

(71) Applicant: International Business Machines Corporation, Armonk, NY (US)

(72) Inventors: Ashim Dutta, Clifton Park, NY (US); Chih-Chao Yang, Glenmont, NY (US); Nicholas Latham, Albany, NY (US); Nicholas Alexander POLOMOFF, Hopewell Junction, NY (US)

(21) Appl. No.: 18/659,901

(22) Filed: May 9, 2024

(51) Int. Cl. H01L 23/522; H01L 21/768

(52) U.S. Cl. CPC H01L 23/5226; H01L 21/76802; H01L 21/76831; H01L 21/76877

(57) ABSTRACT

Embodiments of present invention provide a method of forming a semiconductor structure. The method includes providing a first dielectric layer with a metal line in a first metal level; forming a second dielectric layer on top of the first dielectric layer; creating a trench opening over a via opening in the second dielectric layer; selectively forming a dielectric liner lining sidewalls and a bottom surface of the trench opening and lining sidewalls of the via opening; and filling the trench opening and the via opening with a conductive material to form a trench directly over a via with a common conductive core. A structure formed thereby is also provided.

### BACKGROUND

The present application relates to manufacturing of semiconductor integrated circuits. More particularly, it relates to forming trench and via in a back-end-of-line structure and the resulting structure.

As semiconductor industry moves towards smaller node for increased device density, metal lines in the back-end-of-line (BEOL) structure are placed closer than ever before in order to accommodate communication with densely packed active devices in the front-end-of-line (FEOL) area. The BEOL structure usually includes multiple metal levels with communication among different metal levels being made through various vias that interconnect metal lines at different metal levels.

Currently, a first metal line and a via, which connects the first metal line to a second metal line at a lower metal level, are usually made through a dual-damascene process. During the duel-damascene process of creating a via opening and a trench opening to form the first metal line and the via, excessive etch due to etching an etch-stop layer between the two different metal levels may result in substantially sloped sidewalls of the via opening, causing concerns for possible shorting between a via formed in this via opening and a third metal line that resides next to the second metal line, to which the via connects, at the lower metal level.

### SUMMARY

Embodiments of present invention provide a semiconductor structure. The semiconductor structure may include a first metal level in a first dielectric layer, the first metal level including a metal line; a second metal level over the first metal level and in a second dielectric layer, the second metal level including a trench directly over a via; and a dielectric liner lining sidewalls of the via, the dielectric liner being absent at a bottom and a top of the via. The dielectric liner protects a corner between the trench and the via during an etch process of forming the structure.

In one embodiment, the dielectric liner further lines sidewalls of the trench and a portion of a bottom of the trench, the dielectric liner being in direct contact with the second dielectric layer.

In another embodiment, the dielectric liner conformally lines sidewalls of the trench; a portion of a bottom of the trench; and the sidewalls of the via, and where the dielectric liner has a dielectric constant that is higher than a dielectric constant of the first dielectric layer and the second dielectric layer.

In a further embodiment, the trench and the via are formed through a dual-damascene process to have a common conductive core.

According to one embodiment, the semiconductor structure of further includes a metallic liner lining a surface of the common conductive core of the trench and the via of the second metal level.

In one embodiment, a portion of the metallic liner lining a lower portion of the via fills a notch vertically underneath the dielectric liner, where the notch is between the dielectric liner and an etch-stop layer above the first dielectric layer.

In another embodiment, the via of the second metal level is conductively connected to the metal line of the first metal level via the metallic liner.

According to another embodiment, the semiconductor structure further includes one or more etch-stop layers between the first dielectric layer and the second dielectric layer, where the etch-stop layers are either aluminum-oxide or aluminum-nitride.

Embodiments of present invention further provide a method of forming a semiconductor structure. The method includes providing a first dielectric layer with a metal line in a first metal level; forming a second dielectric layer on top of the first dielectric layer; creating a trench opening over a via opening in the second dielectric layer; selectively forming a dielectric liner lining sidewalls and a bottom surface of the trench opening and lining sidewalls of the via opening; and filling the trench opening and the via opening with a conductive material to form a trench directly over a via with a common conductive core. The dielectric liner protects the corner between the trench and the via during an etch process of forming the structure.

In one embodiment, selectively forming the dielectric liner includes covering a bottom of the via opening with a self-assembled monolayer (SAM); depositing the dielectric liner on the sidewalls and the bottom surface of the trench opening and on the sidewalls of the via opening in a process selective to the SAM; and removing the SAM to expose the bottom of the via opening.

According to one embodiment, the method further includes, after removing the SAM, selectively removing a portion of an etch-stop layer exposed at the bottom of the via opening, the etch-stop layer being directly above the metal line of the first metal level and between the first dielectric layer and the second dielectric layer. The dielectric liner protects rest of the structure while the portion of the etch-stop layer is being removed.

In another embodiment, covering the bottom of the via opening with the SAM includes forming the SAM on the portion of the etch-stop layer in a process selective to the second dielectric layer.

According to another embodiment, the method further includes, before filling the trench opening and the via opening with the conductive material, forming a metallic liner on top of the dielectric liner and on top of the metal line of the first metal level exposed by the via opening.

In yet another embodiment, creating the trench opening over the via opening includes creating the trench opening in the second dielectric layer; filling the trench opening with a sacrificial material; creating an opening through the sacrificial material and the second dielectric layer underneath the sacrificial material; and removing the sacrificial material to expose the via opening in the second dielectric layer and the trench opening that is directly over the via opening.

### BRIEF DESCRIPTION OF THE DRAWINGS

The present invention will be understood and appreciated more fully from the following detailed description of embodiments of present invention, taken in conjunction with accompanying drawings of which:

FIGS. 1 to 11 are demonstrative illustrations of cross-sectional views of a semiconductor structure at various steps of manufacturing thereof according to one embodiment of present invention; and

FIG. 12 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

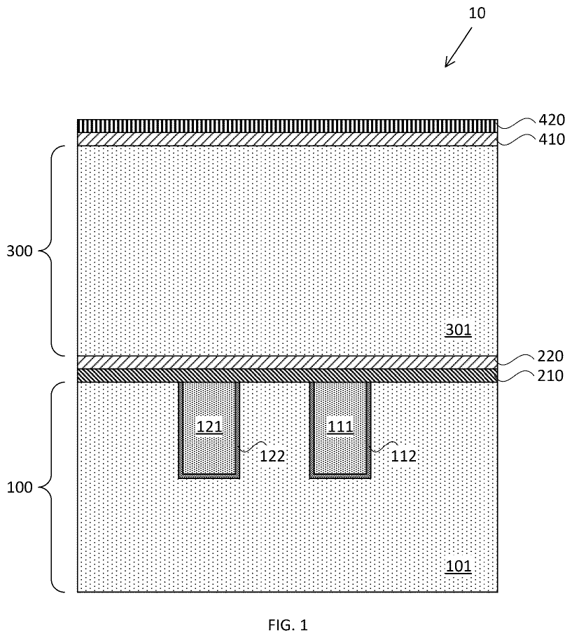

FIG. 1 is a demonstrative illustration of cross-sectional view of a semiconductor structure in a step of manufacturing thereof according to one embodiment of present invention. More specifically, embodiments of present invention provide receiving, or forming, a semiconductor structure 10 that includes a first metal level 100 in a first dielectric layer 101. Here, the semiconductor structure 10 may be an interconnect structure and more particularly a damascene interconnect structure. The first metal level 100 may include one or more metal lines such as, for example, a first metal line 111 and a second metal line 121. The first and the second metal line 111 and 121 may be covered, at a bottom and sidewalls thereof, by a metallic liner such as by metallic liners 112 and 122 respectively. The metallic liners 112 and 122 may include or may be made of, for example, titanium (Ti), titanium-nitride (TiN), tantalum (Ta), and/or tantalum-nitride (TaN). A top surface of the first and the second metal line 111 and 121 may be made coplanar with the first dielectric layer 101 through, for example, a chemical-mechanical-polishing (CMP) process. The first dielectric layer 101 may be made of low-k dielectric material such as, for example, SiCOH, SiCO, and SiOCN.

Embodiments of present invention further provide forming a bilayer cap covering the first dielectric layer 101 and the first and the second metal lines 111 and 121 embedded there. In one embodiment, the bilayer cap may include a first etch-stop layer (ESL) 210 made of, for example, aluminum-oxide (AlOx) or aluminum-nitride (AlN) and a second ESL 220 on top of the first ESL 210. The second ESL 220 may be a layer of silicon-oxycarbide (SiOC) or other suitable etch-stop material. Here, It is to be noted that embodiments of present invention are not limited in this aspect and other types of caps may be used as etch-stop layer or layers to cover the first dielectric layer 101. For example, a trilayer cap may be used that includes, for example, a SiOC layer sandwiched between two layers of AlOx or AlN.

Embodiments of present invention provide forming a second dielectric layer 301 above the first dielectric layer 101, via the first and the second ESL 210 and 220, to form a second metal level 300. The second dielectric layer 301 may be formed, for example through a deposition process such as a chemical-vapor-deposition (CVD) process, a plasma-enhanced CVD (PECVD), and/or a physical-vapor-deposition (PVD) process to have a thickness ranging from about 50 nm to about 500 nm. Next, embodiments of present invention provide proceeding to form the second metal level 300 through a dual-damascene process by forming a sacrificial silicon-nitride (SiN) layer 410 on top of the second dielectric layer 301 and a titanium-nitride (TiN) layer 420 on top of the sacrificial SiN layer 410. The TiN layer 420, together with the sacrificial SiN layer 410, may be subsequently used to form a hard mask for forming metal lines such as trenches and vias of the second metal level 300 in the second dielectric layer 301.

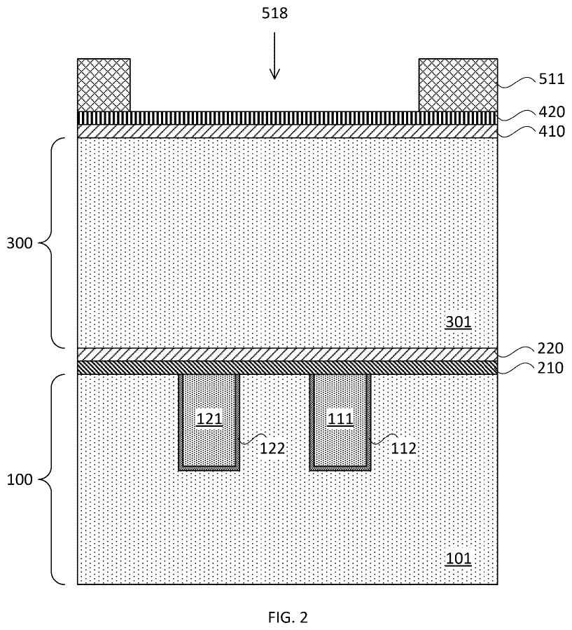

FIG. 2 is a demonstrative illustration of cross-sectional view of a semiconductor structure in a step of manufacturing thereof according to one embodiment of present invention. More specifically, following the step illustrated in FIG. 1, embodiments of present invention provide forming a soft mask 511 on top of the TiN layer 420. The soft mask 511 may be formed from a photoresist layer which is patterned through, for example, a lithographic patterning process. In a trench first dual-damascene process, the soft mask 511 may be patterned to include one or more openings corresponding to one or more metal lines, such as trenches, to be formed in the second dielectric layer 301. For example, as is illustrated in FIG. 2, the soft mask 511 may include an opening 518 that corresponds to a trench to be formed in the second dielectric layer 301.

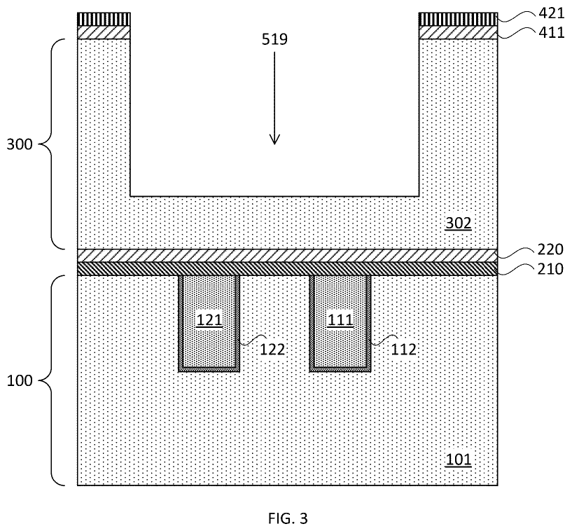

FIG. 3 is a demonstrative illustration of cross-sectional view of a semiconductor structure in a step of manufacturing thereof according to one embodiment of present invention. More specifically, following the step illustrated in FIG. 2, embodiments of present invention provide transferring the pattern of openings in the soft mask 511 onto the TiN layer 420 and underneath sacrificial SiN layer 410 to form a hard mask 421/411, which includes a TiN layer 421 and a sacrificial SiN layer 411 underneath the TiN layer 421. Next, embodiments of present invention provide selectively etching the second dielectric layer 301 through the hard mask 421/411 and the soft mask 511, for example through a reactive-ion-etch (RIE) process, to create a trench opening 519 that is partially into the second dielectric layer 301. The creation of the trench opening 519 transforms the second dielectric layer 301 into a second dielectric layer 302. After the creation of the trench opening 519, the soft mask 511 may be removed through, for example, an ash process. The ash process may be an oxygen-based, or nitrogen/hydrogen-based plasma etch process.

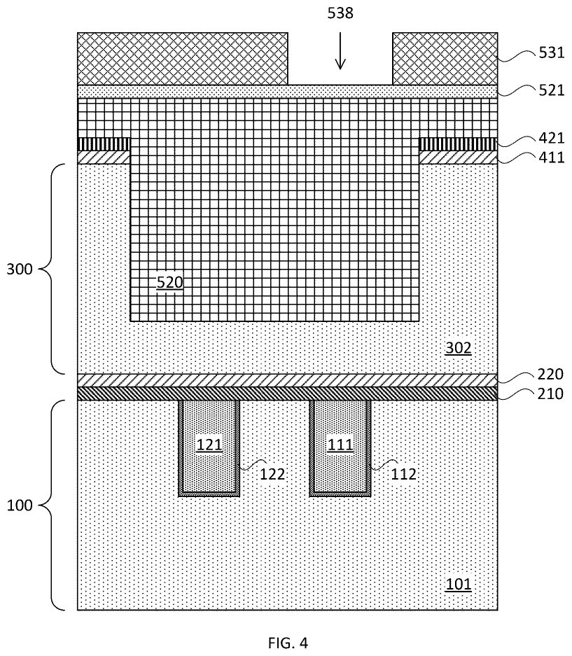

FIG. 4 is a demonstrative illustration of cross-sectional view of a semiconductor structure in a step of manufacturing thereof according to one embodiment of present invention. More specifically, following the step illustrated in FIG. 3, embodiments of present invention provide filling the trench opening 519 with a sacrificial material such as, for example, an organic planarization (OPL) layer 520. The OPL layer 520 may fully fill the trench opening 519 and cover a top surface of the TiN layer 421 of the hard mask 421/411. Next, embodiments of present invention provide forming a silicon-based anti-reflective coating (SiARC) layer 521 on top of the OPL layer 520 and depositing a photoresist layer on top of the SiARC layer 521. The photoresist layer may subsequently be patterned into a soft mask 531, through a lithographic patterning process. The soft mask 531 may include one or more openings such as an opening 538. The opening 538 may be formed to be substantially aligned with a via opening that is intended to be formed in the second dielectric layer 302. The intended via opening in-turn may be substantially aligned with the first metal line 111 of the first metal level 100.

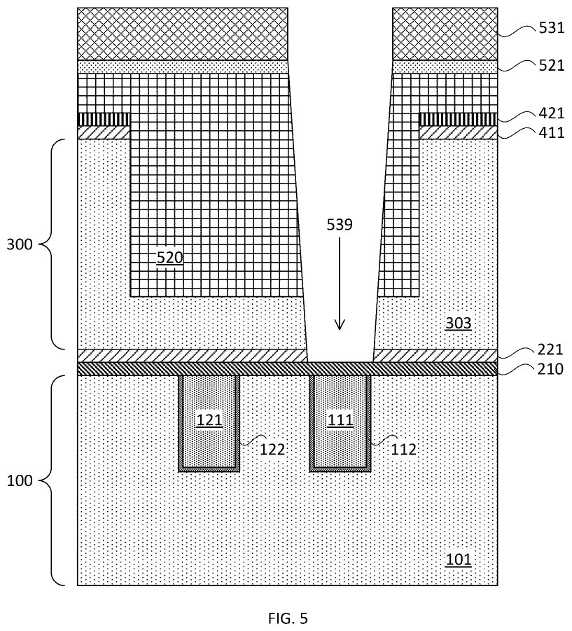

FIG. 5 is a demonstrative illustration of cross-sectional view of a semiconductor structure in a step of manufacturing thereof according to one embodiment of present invention. More specifically, following the step illustrated in FIG. 4, embodiments of present invention provide selectively etching, through the opening 538, the SiARC layer 521, the OPL layer 520, the second dielectric layer 302, and the second ESL 220, at least partially, above the first ESL 210. The selective etch process may stop at the first ESL 210 thereby creating a deep opening that goes through the OPL layer 520 and the second dielectric layer 302 and may thus create a via opening 539 in the second dielectric layer 302. In the meantime, the selective etch process may transform the second dielectric layer 302 into a second dielectric layer 303 and transform the second ESL 220 into a second ESL 221.

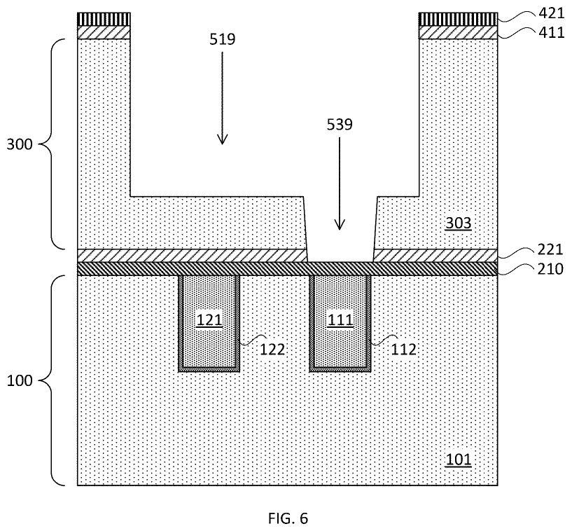

FIG. 6 is a demonstrative illustration of cross-sectional view of a semiconductor structure in a step of manufacturing thereof according to one embodiment of present invention. More specifically, following the step illustrated in FIG. 5, embodiments of present invention provide selectively removing the soft mask 531, the SiARC layer 521, and the OPL layer 520 to expose the trench opening 519 and the via opening 539. As is demonstratively illustrated in FIG. 6, the trench opening 519 is made directly over the via opening 539 and the via opening 539 exposes a portion of the first ESL 210 between the first dielectric layer 101 and the second dielectric layer 301. After the removal of the OPL layer 520, an ash process may be applied to remove any residue of the OPL layer 520, if any, that still remain in the trench opening 519 and the via opening 539.

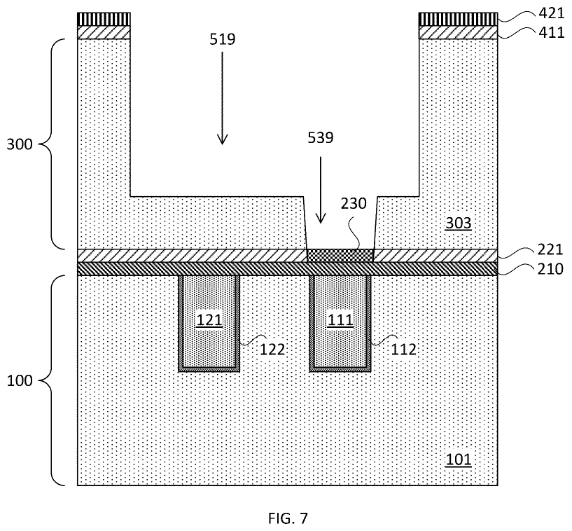

FIG. 7 is a demonstrative illustration of cross-sectional view of a semiconductor structure in a step of manufacturing thereof according to one embodiment of present invention. More specifically, following the step illustrated in FIG. 6, embodiments of present invention provide selectively forming a protective layer 230 at the bottom of the via opening 539 directly above the exposed portion of the first ESL 210. In one embodiment, the first ESL 210 may be a layer of AlOx or AIN, and a self-assembled monolayer (SAM) may be formed directly on top of the first ESL 210 of AlOx or AIN material. The SAM may be a layer of molecules having a thickness approximately equal to a length of the molecule and sometimes may include a carbon backbone of about 6-18 carbon atoms. The layer of molecules may attach to a surface, for example by a chemical bond, and adopt a preferred orientation with respect to that surface and, for example, with respect to each other. More particularly, the SAM may include an organized layer of amphiphilic molecules where one end of the molecule, being referred to as the “head group”, may have a specific affinity for a substrate. The head group may be designed to chemically graft to the substrate based on its surface chemistry. The head group may be connected to an alkyl chain in which a tail end can be functionalized. According to one embodiment, the SAM, such as an octadecylphosphonic acid (ODPA) SAM for example, may selectively adhere to the material of AlOx or AIN and not form, deposit, or adhere to low-k dielectric material such as the surrounding second dielectric layer 303. Consequently, the protective layer 230 of SAM may be formed only at the bottom of the via opening 539, while sidewalls and the bottom of the trench opening 519 and sidewalls of the via opening 539 may remain being exposed.

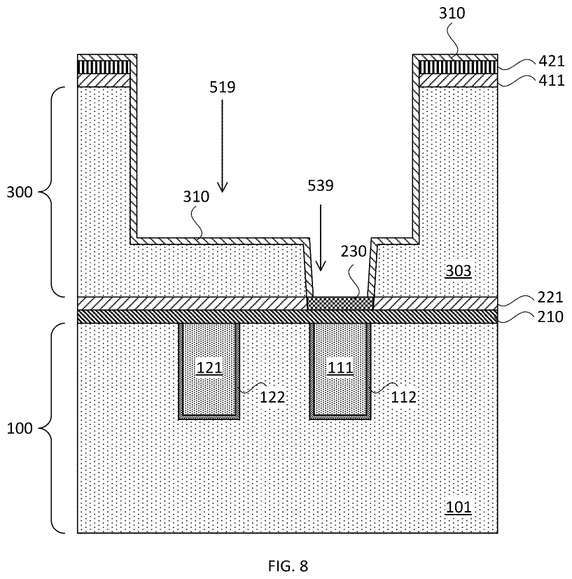

FIG. 8 is a demonstrative illustration of cross-sectional view of a semiconductor structure in a step of manufacturing thereof according to one embodiment of present invention. More specifically, following the step illustrated in FIG. 7, embodiments of present invention provide forming a dielectric liner lining the exposed sidewalls and the bottom of the trench opening 519 and sidewalls of the via opening 539. In other words, the dielectric liner 310 is formed to be in direct contact with the second dielectric layer 303. In one embodiment, the dielectric liner 310 may be a layer, or a conformal layer, of a moderate or high-k dielectric material such as, for example, silicon-oxide (SiOx), silicon-nitride (SiN), silicon-carbide (SiC), hafnium-oxide (HfOx), and/or lanthanum-oxide (LaOx). In other words, the dielectric material of the dielectric liner 310 may have a dielectric constant that is at least higher than the dielectric constant of the second dielectric layer 301 and may be higher than the dielectric constant of the first dielectric layer 101 as well.

By having a higher dielectric constant than the second dielectric layer 303 or by being a high-k dielectric layer, the dielectric liner 310 helps protect the second dielectric layer 303, particularly a corner portion between the trench opening 519 and the via opening 539, from being etched during subsequent etch process. In other words, the dielectric liner 310 helps prevent corner erosion and via blow out in the process of forming a via in the via opening 539 as well as a trench in the trench opening 519. The dielectric liner 310 may be selectively formed, through an area-selective deposition process, only on surfaces of dielectric material such as the second dielectric layer 303 but may not form on top of the protective layer 230 of SAM, thereby leaving the protective layer 230 exposed. In one embodiment, the area-selective deposition process may be an atomic-layer-deposition (ALD) process or a plasma-enhanced atomic-layer-deposition (PEALD) process. In one embodiment, the dielectric liner 310 may be formed conformally to line the sidewalls and bottom surface of the trench opening 519 and the sidewalls of the via opening 539. By the nature of the area-selective deposition process, no dielectric liner 310 is formed on top of the protective layer 230.

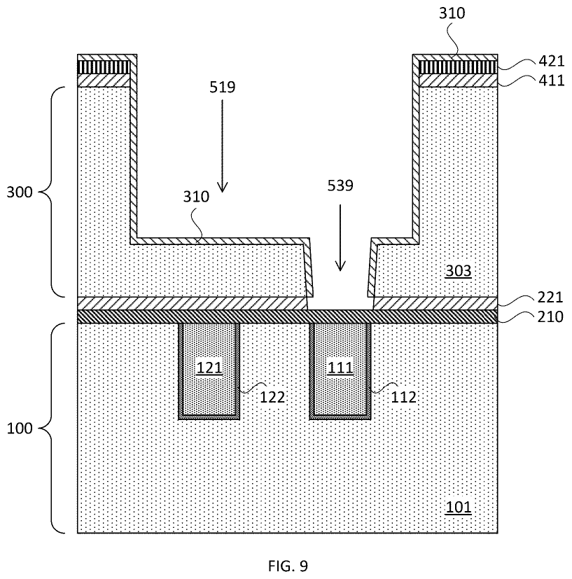

FIG. 9 is a demonstrative illustration of cross-sectional view of a semiconductor structure in a step of manufacturing thereof according to one embodiment of present invention. More specifically, following the step illustrated in FIG. 8, embodiments of present invention provide selectively removing the protective layer 230 of SAM to expose a portion of the first ESL 210. As is demonstratively illustrated in FIG. 9, the removal of the protective layer 230 may thereby create one or more notches vertically below and underneath the dielectric liner 310. The one or more notches may be above the first ESL 210 and immediately adjacent to sidewalls of the second ESL 221 to have a thickness of the second ESL 221. The SAM of protective layer 230 may be removed or lifted through, for example, an ash process. The ash process may leave the dielectric liner 310 substantially unaffected.

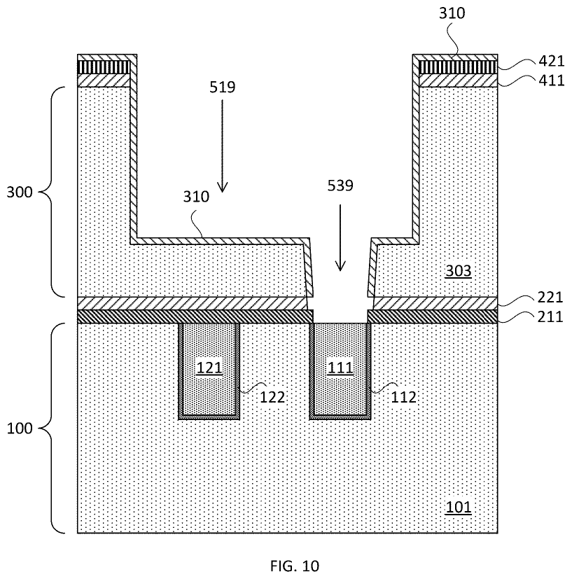

FIG. 10 is a demonstrative illustration of cross-sectional view of a semiconductor structure in a step of manufacturing thereof according to one embodiment of present invention. More specifically, following the step illustrated in FIG. 9, embodiments of present invention provide removing the portion of the first ESL 210 exposed by the via opening 539 to expose the underneath first metal line 111 of the first metal level 100. With the dielectric liner 310 covering and protecting the exposed second dielectric layer 303, the exposed portion of the first ESL 210 may be selectively removed in a directional etch process such as a RIE process.

With the dielectric liner 310 protecting the corner between the trench opening 519 and the via opening 539, the vertically exposed portion of the first ESL 210 may be selectively etched away while the shape of the via opening 539 remains substantially unchanged. In other words, the via opening 539 may have a much steeper sidewall compared with other via openings that may be created in a conventional process without any protection for the corner regions. Consequently, the sidewalls of the via opening 539 may remain to have an angle, between the bottom surface of the trench opening 519 and sidewalls of the via opening 539, in ranging from about 90 degrees to about 105 degrees. The removal of the exposed portion of the first ESL 210 transforms the first ESL 210 into a first ESL 211. As is demonstratively illustrated in FIG. 10, in one embodiment, sidewalls of the first ESL 211 may be substantially aligned with the dielectric liner 310. With a vertical bottom of the dielectric liner 310 at or above a level of the second ESL 221, sidewalls of the second ESL 221 and the first ESL 211 may not be covered by the dielectric liner 310. On the other hand, the one or more notches may be maintained between the dielectric liner 310 and the first ESL 211 and immediately adjacent to the sidewalls of the second ESL 221.

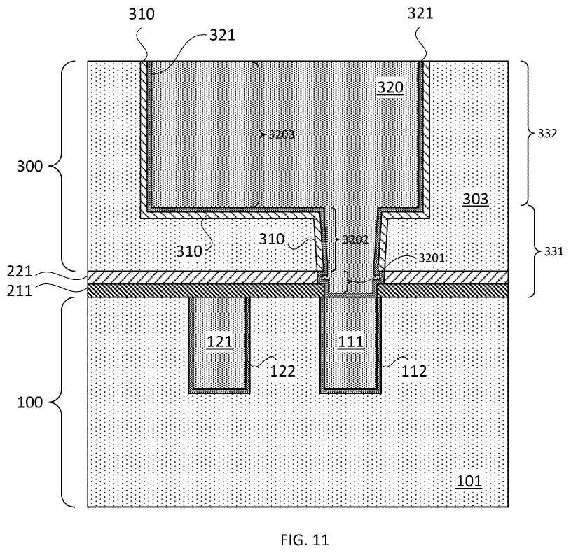

FIG. 11 is a demonstrative illustration of cross-sectional view of a semiconductor structure in a step of manufacturing thereof according to one embodiment of present invention. More specifically, following the step illustrated in FIG. 10, embodiments of present invention provide continuing the damascene process by performing metallization of the trench opening 519 and the via opening 539. More particularly, a metallic liner 321 may first be formed, for example a deposition process, in the trench opening 519 and the via opening 539. As is demonstratively illustrated in FIG. 11, the metallic liner 321 may be a conformal metallic liner and a lower portion of the metallic liner 321 may be formed in the notch between the dielectric liner 310 and the first ESL 211. An upper portion of the metallic liner 321 may be formed directly on top of the dielectric liner 310. In the meantime, the first metal line 111 of the first metal level 100 may be covered by the metallic liner 321 as well.

After forming the metallic liner 321, a conductive material may be used to fill the remaining portion of the trench opening 519 and the via opening 539 to form a common conductive core 320 of a trench and a via. The conductive material may be, for example, copper (Cu), tungsten (W), aluminum (AI), cobalt (Co), ruthenium (Ru), or other suitable conductive materials. The common conductive core 320 may thus be covered by the metallic liner 321. The common conductive core 320 may have a first portion 3201, a second portion 3202, and a third portion 3203. The first portion 3201 and the second portion 3202 form a via 331 and the third portion 3203 forms a trench 332, and there is no liner between the via 331 and the trench 332. In one embodiment, the first portion 3201 of the via 331 may have an outward edge formed in the notch between the dielectric liner 310 and the first ESL 211. The outward edge, together with the metallic liner lining thereof, may have a combined thickness that is substantially same as a thickness of the second ESL 221.

The dielectric liner 310 may cover sidewalls and a bottom of the trench 332 and sidewalls of the via 331. The dielectric liner 310 may be absent at a bottom of the via 331. In other words, the semiconductor structure 10, or interconnect structure, may be devoid of the dielectric liner 310 at a bottom of the via of the second metal level 300.

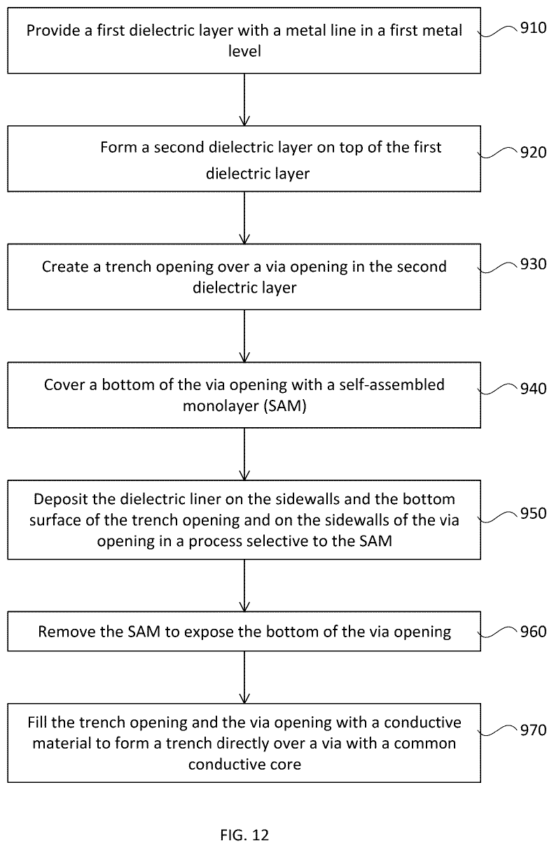

FIG. 12 is a demonstrative illustration of a flow-chart of a method of manufacturing a semiconductor structure according to embodiments of present invention. The method includes (910) providing a first dielectric layer with a metal line in a first metal level; (920) forming a second dielectric layer on top of the first dielectric layer; (930) creating a trench opening over a via opening in the second dielectric layer; (940) covering a bottom of the via opening with a self-assembled monolayer (SAM); (950) depositing a dielectric liner on the sidewalls and the bottom surface of the trench opening and on the sidewalls of the via opening in a process selective to the SAM; and (960) removing the SAM to expose the bottom of the via opening; and (970) filling the trench opening and the via opening with a conductive material to form a trench directly over a via with the trench and the via having a common conductive core.

Various examples may possibly be described by one or more of the following features in the following numbered clauses:
Clause 1: A semiconductor structure comprising: a first metal level in a first dielectric layer, the first metal level including a metal line; a second metal level over the first metal level and in a second dielectric layer, the second metal level including a trench directly over a via; and a dielectric liner lining sidewalls of the via, the dielectric liner being absent at a bottom and a top of the via.
Clause 2: The semiconductor structure of clause 1, wherein the dielectric liner further lines sidewalls of the trench and a portion of a bottom of the trench, the dielectric liner being in direct contact with the second dielectric layer.
Clause 3: The semiconductor structure of clause 1, wherein the dielectric liner conformally lines sidewalls of the trench; a portion of a bottom of the trench; and the sidewalls of the via, and wherein the dielectric liner has a dielectric constant that is higher than a dielectric constant of the first dielectric layer and the second dielectric layer.
Clause 4: The semiconductor structure of clause 1, wherein the trench and the via are formed through a dual-damascene process to have a common conductive core.
Clause 5: The semiconductor structure of clause 4, further comprising a metallic liner lining a surface of the common conductive core of the trench and the via of the second metal level.
Clause 6: The semiconductor structure of clause 5, wherein a portion of the metallic liner lining a lower portion of the via fills a notch vertically underneath the dielectric liner, wherein the notch is between the dielectric liner and an etch-stop layer above the first dielectric layer.
Clause 7: The semiconductor structure of clause 6, wherein the via of the second metal level is conductively connected to the metal line of the first metal level via the metallic liner.
Clause 8: The semiconductor structure of clause 1, further comprising one or more etch-stop layers between the first dielectric layer and the second dielectric layer, wherein the etch-stop layers are either aluminum-oxide or aluminum-nitride.
Clause 9: A method of forming a semiconductor structure, the method comprising: providing a first dielectric layer with a metal line in a first metal level; forming a second dielectric layer on top of the first dielectric layer; creating a trench opening over a via opening in the second dielectric layer; selectively forming a dielectric liner lining sidewalls and a bottom surface of the trench opening and lining sidewalls of the via opening; and filling the trench opening and the via opening with a conductive material to form a trench directly over a via with a common conductive core.
Clause 10: The method of clause 9, wherein selectively forming the dielectric liner comprises: covering a bottom of the via opening with a self-assembled monolayer (SAM); depositing the dielectric liner on the sidewalls and the bottom surface of the trench opening and on the sidewalls of the via opening in a process selective to the SAM; and removing the SAM to expose the bottom of the via opening.
Clause 11: The method of clause 10, further comprising, after removing the SAM, selectively removing a portion of an etch-stop layer exposed at the bottom of the via opening, the etch-stop layer being directly above the metal line of the first metal level and between the first dielectric layer and the second dielectric layer.
Clause 12: The method of clause 11, wherein covering the bottom of the via opening with the SAM comprises forming the SAM on the portion of the etch-stop layer in a process selective to the second dielectric layer.
Clause 13: The method of clause 9, further comprising, before filling the trench opening and the via opening with the conductive material, forming a metallic liner on top of the dielectric liner and on top of the metal line of the first metal level exposed by the via opening.
Clause 14: The method of clause 9, wherein creating the trench opening over the via opening comprises: creating the trench opening in the second dielectric layer; filling the trench opening with a sacrificial material; creating an opening through the sacrificial material and the second dielectric layer underneath the sacrificial material; and removing the sacrificial material to expose the via opening in the second dielectric layer and the trench opening that is directly over the via opening.
Clause 15: An interconnect structure comprising: a first metal level in a first dielectric layer, the first metal level including a metal line; a second metal level over the first metal level in a second dielectric layer, the second metal level including a trench directly over a via; and a dielectric liner lining sidewalls of the via, sidewalls of the trench, and a bottom of the trench; wherein the dielectric liner is absent at a bottom of the via such that the via is conductively connected to the metal line of the first metal level via a metallic liner.
Clause 16: The interconnect structure of clause 15, wherein the dielectric liner is a conformal dielectric liner of moderate or high-k dielectric material, the moderate or high-k dielectric material being selected from a group consisting of silicon-nitride, silicon-oxide, silicon-carbide, hafnium-oxide, and lanthanum-oxide.
Clause 17: The interconnect structure of clause 15, wherein the trench and the via are formed through a dual-damascene process such that the dielectric liner is absent between the trench and the via.
Clause 18: The interconnect structure of clause 15, further comprising a metallic liner lining the trench and the via.
Clause 19: The interconnect structure of clause 18, wherein a portion of the metallic liner covering a lower portion of the via is vertically underneath the dielectric liner.
Clause 20: The interconnect structure of clause 15, wherein a lower portion of the via has an outward edge.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first metal level in a first dielectric layer, the first metal level including a metal line;
a second metal level over the first metal level and in a second dielectric layer, the second metal level including a trench directly over a via; and
a dielectric liner lining sidewalls of the via, the dielectric liner being absent at a bottom and a top of the via.

2. The semiconductor structure of claim 1, wherein the dielectric liner further lines sidewalls of the trench and a portion of a bottom of the trench, the dielectric liner being in direct contact with the second dielectric layer.

3. The semiconductor structure of claim 1, wherein the dielectric liner conformally lines sidewalls of the trench; a portion of a bottom of the trench; and the sidewalls of the via, and wherein the dielectric liner has a dielectric constant that is higher than a dielectric constant of the first dielectric layer and the second dielectric layer.

4. The semiconductor structure of claim 1, wherein the trench and the via are formed through a dual-damascene process to have a common conductive core.

5. The semiconductor structure of claim 4, further comprising a metallic liner lining a surface of the common conductive core of the trench and the via of the second metal level.

6. The semiconductor structure of claim 5, wherein a portion of the metallic liner lining a lower portion of the via fills a notch vertically underneath the dielectric liner, wherein the notch is between the dielectric liner and an etch-stop layer above the first dielectric layer.

7. The semiconductor structure of claim 6, wherein the via of the second metal level is conductively connected to the metal line of the first metal level via the metallic liner.

8. The semiconductor structure of claim 1, further comprising one or more etch-stop layers between the first dielectric layer and the second dielectric layer, wherein the etch-stop layers are either aluminum-oxide or aluminum-nitride.

9. A method of forming a semiconductor structure, the method comprising:
providing a first dielectric layer with a metal line in a first metal level;
forming a second dielectric layer on top of the first dielectric layer;
creating a trench opening over a via opening in the second dielectric layer;
selectively forming a dielectric liner lining sidewalls and a bottom surface of the trench opening and lining sidewalls of the via opening; and
filling the trench opening and the via opening with a conductive material to form a trench directly over a via with a common conductive core.

10. The method of claim 9, wherein selectively forming the dielectric liner comprises:
covering a bottom of the via opening with a self-assembled monolayer (SAM);
depositing the dielectric liner on the sidewalls and the bottom surface of the trench opening and on the sidewalls of the via opening in a process selective to the SAM; and
removing the SAM to expose the bottom of the via opening.

11. The method of claim 10, further comprising, after removing the SAM, selectively removing a portion of an etch-stop layer exposed at the bottom of the via opening, the etch-stop layer being directly above the metal line of the first metal level and between the first dielectric layer and the second dielectric layer.

12. The method of claim 11, wherein covering the bottom of the via opening with the SAM comprises forming the SAM on the portion of the etch-stop layer in a process selective to the second dielectric layer.

13. The method of claim 9, further comprising, before filling the trench opening and the via opening with the conductive material, forming a metallic liner on top of the dielectric liner and on top of the metal line of the first metal level exposed by the via opening.

14. The method of claim 9, wherein creating the trench opening over the via opening comprises:
creating the trench opening in the second dielectric layer;
filling the trench opening with a sacrificial material;
creating an opening through the sacrificial material and the second dielectric layer underneath the sacrificial material; and
removing the sacrificial material to expose the via opening in the second dielectric layer and the trench opening that is directly over the via opening.

15. An interconnect structure comprising:
a first metal level in a first dielectric layer, the first metal level including a metal line;
a second metal level over the first metal level in a second dielectric layer, the second metal level including a trench directly over a via; and
a dielectric liner lining sidewalls of the via, sidewalls of the trench, and a bottom of the trench;
wherein the dielectric liner is absent at a bottom of the via such that the via is conductively connected to the metal line of the first metal level via a metallic liner.

16. The interconnect structure of claim 15, wherein the dielectric liner is a conformal dielectric liner of moderate or high-k dielectric material, the moderate or high-k dielectric material being selected from a group consisting of silicon-nitride, silicon-oxide, silicon-carbide, hafnium-oxide, and lanthanum-oxide.

17. The interconnect structure of claim 15, wherein the trench and the via are formed through a dual-damascene process such that the dielectric liner is absent between the trench and the via.

18. The interconnect structure of claim 15, further comprising a metallic liner lining the trench and the via.

19. The interconnect structure of claim 18, wherein a portion of the metallic liner covering a lower portion of the via is vertically underneath the dielectric liner.

20. The interconnect structure of claim 15, wherein a lower portion of the via has an outward edge.
